(19) United States
(12) Patent Application Publication
(10) Pub. No.: US 2005/0012094 A1
(43) Pub. Date: Jan. 20, 2005

(54) Organic semiconductor device and method for manufacturing the same

(76) Inventor: Byoung-Choo Park, Kyonggi-do (KR)

Correspondence Address: ST. ONGE STEWARD JOHNSTON & REENS, LLC, 986 BEDFORD STREET, STAMFORD, CT, 06905-5619, US

(21) Appl. No.: 10/918,873

(22) Filed: Aug. 16, 2004

Related U.S. Application Data
(63) Continuation of application No. PCT/KR03/00306, filed on Feb. 13, 2003.

(30) Foreign Application Priority Data
Feb. 15, 2002 (KR) 10-2002-0008268

(51) Int. Cl. H01L 21/00; H01L 33/00

(52) U.S. Cl. 257/40; 438/99; 257/88; 438/47; 257/103

(57) ABSTRACT

A method for manufacturing an organic semiconductor device including an organic electro-luminescent device composed of a plurality of pixels, which display high quality image information. Insulating film patterns composed of insulating materials having a lower optical damage threshold than the optical damage threshold of a substrate are formed between pixel elements on the substrate. Organic layers including a light-emitting organic layer and electrodes are formed on the substrate where the insulating films are formed. Focused laser beams are irradiated to entirely remove the organic layers and electrode materials formed on the insulating film patterns and remove the insulating film patterns partially or entirely in view of thickness and, thereby forming a plurality of pixels. The optical damage process using laser beam irradiation is performed under the vacuum, or non-moisture and non-oxygen inert gas flows, to prevent the devices from being contaminated by residual products.

This application is a continuation of pending International Patent Application No. PCT/KR2003/000306 filed Feb. 13, 2003, which designates the United States and claims priority of pending Korean Application No. 2002-8268, filed Feb. 15, 2002.

### FIELD OF THE INVENTION

The present invention relates to an organic semiconductor device including an OELD (Organic Electro-luminescent Device) and a method for manufacturing the same, and more particularly to, an organic semiconductor device and a method for manufacturing the same wherein by using an optical damage phenomenon a plurality of elements or pixels of the organic semiconductor device are easily separated or the organic semiconductor device of complicated shape is also easily fabricated so that a producing yield of the organic semiconductor device is improved, contamination generated during the fabrication is minimized and an operation reliability of the device is enhanced.

### BACKGROUND OF THE INVENTION

In general, organic semiconductor devices including organic diode devices and organic transistor devices are based on the electrical semi-conductivity related to an HOMO (Highest Occupied Molecular Orbital) state and an LUMO (Lowest Unoccupied Molecular Orbital) state of electronic energy levels of organic materials. Examples of organic diode devices include organic light emitting diodes or organic electro-luminescent (EL) diodes, and examples of organic transistor devices include organic FETs (Field Effect Transistors), organic TFTs (Thin Film Transistors), organic SITs (Static Induction Transistors), organic top gate SITs, organic triodes, organic grid transistors, organic thyristors, or organic bipolar transistors.

Since the organic layers of the organic semiconductor devices are formed on the substrate, a photolithography method for separating pixels or elements, which are composed of organic materials, cannot be applied. Therefore, organic or inorganic separators having complicated structures have been used for separating the pixels or elements composed of organic materials.

The present invention relates to a process for separating or cutting the organic pixels or elements formed on the substrate, in a manufacturing process of the above-mentioned various organic semiconductor devices. The present process can be widely applied to any kind of organic semiconductor devices regardless of their structures. Hereinafter, the process of the present invention will be described with reference to the OELD that has the simplest structure among the organic semiconductor devices.

The OELD is one of the representative flat displays such as an LCD (Liquid Crystal Display), a PDP (Plasma Display Panel) or a FED (Field Emission Display). Since the OELD has a fast response time below a few μs under low driving voltage and is a self-emission device, which does not require back light source, it has advantages of excellent brightness and wide viewing angle with full color display in a visible range. Especially, the OELD can be easily manufactured in a thin film or flexible type and thus it is also possible to easily achieve mass production.

The conventional single OELD device includes a first electrode, organic layers and a second electrode that are sequentially formed on a transparent substrate. The organic layers include a hole injecting layer for injecting holes and a hole transporting layer for transporting holes from the first electrode, an organic light-emitting layer, and an electronic transporting layer for injecting electrons and transporting electrons from the second electrode, which all have been sequentially formed on the substrate. When a voltage is applied between the first and second electrodes of the OELD, the holes and electrons injected from the first and second electrodes, respectively, are migrated through the hole injecting layer, the hole transporting layer and the electronic transporting layer into the HOMO state and LUMO state of the organic light-emitting layer, and the holes and electrons at each state are recombined to emit light. In order to manufacture the visual information display including EL pixels, a simple and high yield method for producing a plurality of pixels should be used.

The conventional method for simply manufacturing pixel patterns in a passive matrix type monochromatic OELD that composes a plurality of pixels uses a shadow mask. In detail, a plurality of first electrodes (anodes) made of ITO (Indium Tin Oxide), polyaniline or Ag having a high work function are formed on a substrate in the shape of stripe patterns. At least one organic layer constituted by fluorescent organic compounds such as low molecular weight organic compounds or organic polymers is formed on the first electrodes. And then, a plurality of second electrodes (cathodes) made of Al, Mg or Ca having a low work function is formed on the organic layers with being opposite to the first electrodes. Here, the second electrodes are separated from each other by the shadow mask and are formed perpendicularly to the stripes of the first electrodes as stripes. This method is advantageous in view of a simple formation of the pixels, but fails to easily form the precise pixels due to the precision limitation of the shadow mask.

U.S. Pat. No. 5,701,055 suggests another method for forming the plurality of pixels of the passive matrix type in a monochromatic OELD, wherein the pixels are separated from one another by an insulating separator. The first electrodes made of materials having a high work function are formed on a substrate in the form of stripe patterns, and organic or inorganic insulating separator stripes are formed perpendicularly to the stripes of the first electrodes on the first electrodes and the substrate. And then, at least one organic layer composed of fluorescent organic compounds, and second electrodes made of materials having a low work function are sequentially formed on the whole surface of the substrate. The insulating separators separate the second electrodes as well as the organic layers from each other so that they are formed perpendicularly to the stripes of the first electrodes as stripes. This method is advantageous to simply and easily form the plurality pixels. However, the organic layers and the second electrodes may not be completely separated due to the imperfect shape of the separator, which reduces precision in pixel formation and also reduces yield.

Japanese Patent Laid-Open 8-315981 suggests another method for separating pixels in a passive matrix type in a full color OELD having a plurality of pixels, by using a shadow mask and an insulating separator. This method is useful for manufacturing a display with an appropriate pixel size. But a structure of separator used in the above patent is complicated. Accordingly, when a display size increases and a pitch between the pixels decreases, it is difficult to separate the pixels.

Further, U.S. Pat. No. 5,814,417 discloses another method for forming pixels in the passive matrix type in a monochromatic OELD by using laser beams. Firstly, first electrodes made of materials having a high work function, such as ITO are formed on a substrate in stripe patterns, and organic or inorganic insulating film stripes are formed perpendicularly to the stripes of the first electrodes on the first electrodes and the substrate. The organic or inorganic insulating films are composed of insulating materials having high insulative and heat-resistant properties not to be damaged by the laser beams. At least one light-emitting organic layer made of luminescent organic compounds is formed on the substrate, and the second electrodes are sequentially formed on the light-emitting organic layer. And then, laser beams are irradiated from the upper side of the second electrodes to the insulating stripes and remove the light-emitting organic layer and the second electrode on the insulating stripes so that stripe patterns of the second electrodes are formed. Instead of organic or inorganic insulating films, a laser beam absorption layer for efficiently absorbing the laser beams may be formed on the second electrodes. Thereafter, the laser beams are irradiated to form the stripe patterns of second electrodes, thereby forming separated pixels. It may be also possible to use both the insulating films with low heat absorption and the laser beam absorption layers for efficiently absorbing the laser beams. The laser beams are irradiated to form the stripes patterns of the second electrodes, thereby forming a plurality of pixels separated. This method can be applied to a large size display or a display having a low pixel pitch. However, the pixels may be contaminated by residual products generated during the optical separation process.

U.S. Pat. No. 6,136,622 suggests another method for forming the pixels in the passive matrix type in a OELD by using laser beams. First electrodes of stripes, organic or inorganic insulating films of stripes which are arranged perpendicularly to the stripes of the first electrodes, at least one light-emitting organic layer, and second electrodes are sequentially formed on a substrate according to the method for manufacturing the OELD disclosed in the patent. Here, the organic or inorganic insulating film stripes are made of insulating materials having high insulative and heat-resistant properties not to be damaged by laser beams. In addition to the insulating films, the laser beam absorption layers may be formed on the second electrodes.

Thereafter, the resultant device is covered with a glass cap, and the inside of the device is made under a vacuum condition. Thereafter, the laser beams are irradiated from the upper side of the glass cap onto the light-emitting organic layer and the second electrodes on the insulating stripes, to separate the organic light-emitting layer and the second electrodes from one anothers, thereby forming a plurality of pixels of the OELD. This method uses the vacuum state and the glass cap, and thus can prevent the pixels from being contaminated by residual products generated during the optical separation process. However, a process for forming the vacuum state by using the glass cap during the formation of pixels is complicated.

The above-described conventional methods for forming the plurality of pixels of the OELD are complicated, a producing yield by the conventional methods is very low, and the pixels may be possibly contaminated by the residual products. In addition, there is a problem that image quality and operation reliability of the OELD including the pixels separated by the above-mentioned methods may be deteriorated due to the incompletely separated pixels.

The foregoing problems may be occurred when the organic layers which are included in another kind of organic semiconductor device or which compose pixels of another kind of organic semiconductor device are formed on the substrate. For example, there is a pentacene organic TFT. A nickel gate electrode is formed on a glass substrate at a low temperature, a silicon oxide film is formed thereon as a gate insulating film, and a palladium is sequentially deposited thereon. The resulting structure experiences photolithography so that source/drain electrodes are formed. Pentacene that is an organic material is deposited as an active layer on the whole surface of the substrate on which the source/drain electrodes have been formed. However, since the pentacene active layer needs to be patterned and separated per device so as to form a plurality of organic TFT on the substrate, the separator, a shadow mask or a laser beam mentioned in the above patents can be used for the formation of the organic TFT. As a result, a yield of the organic TFTs decreases, operation quality and reliability of the device using the organic TFT can be deteriorated due to the incomplete separation of the devices.

### SUMMARY OF THE INVENTION

An object of the present invention is to provide a method for easily manufacturing or separating a plurality of organic semiconductor devices from each other.

Another object of the present invention is to provide a method for manufacturing an organic semiconductor device including an OELD, which can minimize possibility of pixel contamination during the production thereof.

Yet another object of the present invention is to provide an organic semiconductor device including an OELD composed of a plurality of pixels, which can improve image quality and operation reliability.

In order to achieve the above-described objects of the invention, a process for manufacturing a plurality of organic semiconductor devices will now be explained.

A glass, quartz or polymer substrate transparent to laser beams, or a semiconductor substrate such as silicon or gallium arsenide is prepared. A plurality of separated organic semiconductor devices will be formed on the substrate. Patterned insulating films having a lower optical damage threshold than the optical damage threshold of the substrate are formed in the areas for separating the organic semiconductor devices from each other. Organic layers are formed on the insulating films and the substrate and then focused laser beams are irradiated onto the patterned insulating films, thereby entirely removing only the organic layers positioned on the insulating films and further removing the insulating films partially or entirely in view of thickness. Therefore, the plurality of separated organic semiconductor devices is finally manufactured.

In detail, in the case that the electrodes are formed on the organic layers, after the electrodes and the organic layers are sequentially formed on the substrate where insulating films are formed with predetermined patterns, the step for irradiating the laser beams is performed. Wherein in the step for irradiating the laser beams, the only organic layers and electrodes positioned on the insulating films are entirely removed and further the insulating films are removed partially or wholly in view of thickness.

As another example, after performing the sequential steps for preparing the substrate, forming electrodes, and forming organic layers on the substrate where insulating films are formed with predetermined patterns; or after performing the sequential steps for preparing the substrate, forming electrodes, forming organic layers, and forming another electrodes on the substrate where insulating films are formed with predetermined patterns, the step for irradiating the laser beams is performed. In the step for irradiating the laser beams, only the organic layers and second electrodes which are positioned on the patterned insulating films are entirely removed and further the insulating films are partially or wholly removed in view of thickness. An OELD is one of the organic semiconductor devices including the second electrodes facing the first electrodes. In this OELD case, pixels of the OELD are also separated by applying the step for irradiating the laser beams.

The patterned insulating films are composed of insulating materials, whose optical damage threshold is lower than that of the substrate. The materials of the insulating films are not specifically limited, but more preferably, made of photo resists, dry resists, organic insulators, or combinations thereof whose optical damage thresholds are less than the glass substrate (˜3 GW/cm² or ˜30 J/cm²). The shapes of the insulating films are not limited either, but preferably, a width of the insulating films is over 10 μm and a thickness thereof ranges from 1 to 10 μm.

As well as the stripe structure, the laser beam damage method can be applied to a processing of complicated device having curved patterns. The laser beams are irradiated onto the upper portions of the insulating films or lower portions of the insulating films. In order to efficiently prevent the pixels from being contaminated by residuals of the insulating materials, organic materials and electrodes which had been removed by the laser beams, the step for irradiating the laser beams is performed under the vacuum or non-moisture and non-oxygen inert gas flows. The laser beams are selected from pulse type of lasers having a wavelength in the region from 0.1 to 2 μm. A width of the focused laser beams is preferably controlled below the width of the insulating films. Laser beam absorption layers are further formed after the step for forming the organic layers or second electrodes in order to facilitate laser beam absorption effects during the laser beam irradiation.

The resultant organic semiconductor devices having the separated pixels or elements by using the laser beam separation process, include a substrate, a plurality of organic layers and a plurality of insulating films. The plurality of organic layers separated from each other by the optical damage is composed of at least one shape of patters. The plurality of insulating films can be formed on the sidewalls of the organic layers and composed of insulating materials having a lower optical damage threshold than the optical damage threshold of the substrate. The insulating films may be formed between the organic layers as well as the sidewalls of the organic layers, and composed of photo resists, dry resists, organic insulators, or combinations thereof.

In more detail, the organic semiconductor device further includes electrodes formed on the organic layers or between the substrate and the organic layers. Wherein laser beam absorption layers for improving laser beam absorption during the laser beam irradiation may be further formed either on the electrodes positioned on the organic layers, or on the organic layers under which the electrodes are formed.

The OELD, one example of the organic semiconductor devices, further includes first electrodes formed between the substrate and the organic layers and second electrodes formed on the organic layers. In addition, the OELD further includes laser beam absorption layers formed on the second electrodes for improving laser beam absorption during the laser beam irradiation.

### BRIEF DESCRIPTION OF THE DRAWINGS

FIGS. 1a through 1e are cross-sectional diagrams illustrating a method for forming the pixels of an OELD in accordance with one embodiment of the present invention;

FIGS. 2a through 2d are cross-sectional diagrams illustrating a method for forming the pixels of the OELD in accordance with another embodiment of the present invention;

FIGS. 3a through 3f are cross-sectional diagrams illustrating a method for forming the pixels of the OELD in accordance with still another embodiment of the present invention; and

FIGS. 4a through 4f are cross-sectional diagrams illustrating a method for forming the pixels of the OELD in accordance with yet still another embodiment of the present invention.

### DETAILED DESCRIPTION OF THE INVENTION

An organic semiconductor device and a method for manufacturing the same in accordance with the present invention will now be described in detail with reference to the accompanying drawings. In the following description, same drawing reference numerals are used for the same elements even in different drawings.

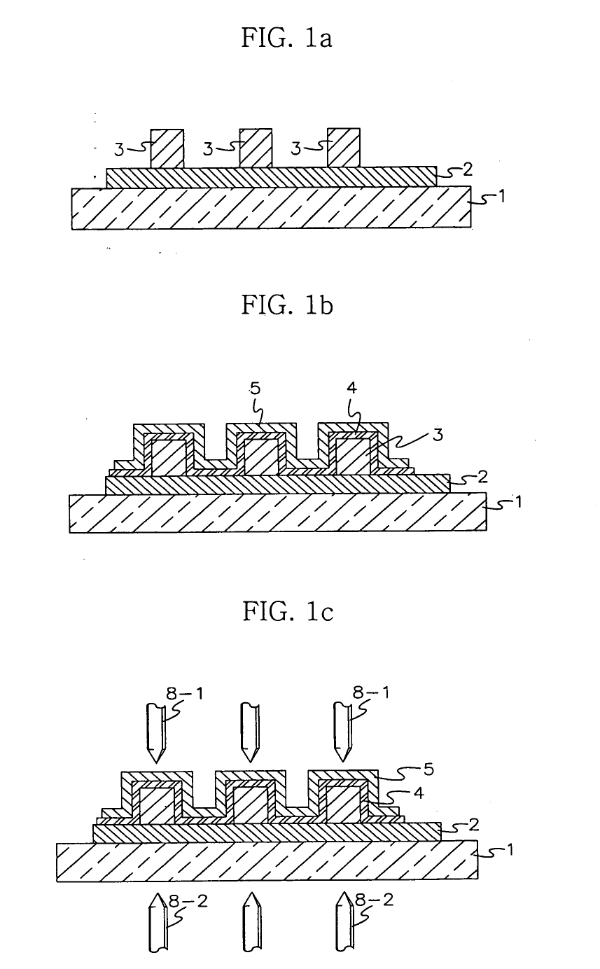

FIGS. 1a through 1e are cross-sectional diagrams illustrating a method for forming pixels of an OELD in accordance with one embodiment of the present invention. Referring to FIG. 1a, a plurality of first electrodes 2 composed of polyaniline, Ag or ITO which having a high work function are formed in a stripe shape, on a glass, quartz or polymer substrate transparent to laser beams which will be later used or a semiconductor substrate 1 such as silicon or gallium arsenide. A plurality of organic or inorganic insulating film stripes 3 are formed perpendicularly to the stripes of the first electrodes 2 on the first electrodes 2 and the substrate. Location of the insulating film stripes 3 becomes pixel separation parts. The organic or inorganic insulating film stripes 3 are composed of materials having high insulation and low optical damage threshold to be easily damaged and removed by general pulse type of laser beams. The organic or inorganic insulating film stripes 3 can be formed in a single layer structure or multi-layer structure. Examples of materials of the insulating film stripes 3 include photo resist, dry resist, organic insulator, photo reactive epoxy compound, azophosphonate polymer, PMMA (polymethylmethacrylate), doped PMMA, acrylic polymer, polyacrylic polymer, polyester, polyimide, fullerene (C60), Si and combinations thereof, which have a lower optical damage threshold than the glass substrate or used substrate materials. However, materials of the insulating films are not limited within the above-mentioned materials. Patterned shapes of the insulating films are not specifically limited, and preferably, a width of the insulating film 3 is over 10 μm and a thickness thereof ranges from 1 to 10 μm in consideration of a size of the OELD currently manufactured.

As shown in FIG. 1b, at least one organic EL layer 4 and the second electrodes 5 are sequentially formed on the substrate 1 where the insulating film stripes 3 are formed. The organic EL layer 4 is comprised by fluorescent organic compounds such as low molecular weight organic compounds or organic polymers. The organic EL layer 4 is made of conductive, non-conductive or semi-conductive organic monomers, oligomers or polymers, and the second electrodes 5 are made of materials having a low work function such as Al, Mg or Ca.

As depicted in FIG. 1c, focused laser beams 8-1 are irradiated from the upper side of the second electrodes 5 onto the insulating film stripes 3, or focused laser beams 8-2 are irradiated from the lower side of the substrate 1 onto the insulating film stripes 3, thereby removing the insulating film stripes 3 by using optical damage phenomenon and then simultaneously removing only the organic layer 4 and the second electrodes 5 which are positioned on the insulating film stripes 3 at the same time. Thus, the second electrodes 5 and the organic EL layer 4 are made perpendicularly to the first electrodes 2, thereby forming a plurality of pixels separated (FIGS. 1d and 1e). Here, an irradiation angle of the laser beams can be selectively set up.

The optical damage, which is distinguished from the general laser beam absorption, is generated from composite effects of 1) electric field break-down, 2) ionization caused by multi-photon absorption, and 3) UV-quantum induced breaking of chemical bond or photochemical mechanism which breaks bonding of the atoms or molecules, where electromagnetic force of the laser beams is higher than bonding force (Van der Waals force) of atoms or molecules of the insulating films.

The laser beams are irradiated onto the insulating film stripes 3 and scanned along the insulating film stripes 3 and therefore the insulating film stripes 3 are removed. In anther way, the insulating film stripes 3 can be removed at a time by positioning a photo mask between the substrate and a laser beam source, by aligning an open area of the photo mask to the insulating film stripes 3, and then by irradiated the laser beams onto the whole surface of the substrate. In still another way, the insulating film stripes 3 can be removed by partially positioning a photo mask between the substrate and a laser beam source, by aligning an open area of the photo mask to the insulating film stripes 3, and then by irradiating the laser beams onto the part surface of the substrate where the photo mask are scanned.

On the other hand, in FIG. 1d, the second electrodes 5, the organic EL layer 4 and the insulating film stripes 3 are entirely removed so as to expose the first electrodes 2. Accordingly, the OELD includes the transparent substrate 1, a plurality of the first electrodes stripes 2, a plurality of organic EL layers 4 arranged perpendicularly to the stripe patterns of the first electrodes 2 as stripe patterns on the first electrodes 2, a plurality of second electrodes 5 formed having similar patterns as the organic EL layers 4 on the organic EL layers 4, and a plurality of insulating film stripes 3a formed on the sidewalls of the organic EL layers 4 so as to expose a part of the first electrodes 2. Wherein the insulating film stripes 3a are composed of insulating materials having a low optical damage threshold.

FIG. 1e shows a state where the insulating film stripes 3 are partially removed, and thus the first electrodes 2 are not exposed at a part where insulating films are formed. Therefore, the OELD of FIG. 1e includes the transparent substrate 1, a plurality of first electrode 2 as stripe patterns on the transparent substrate 1, a plurality of organic EL layers 4 arranged perpendicularly to the stripe patterns of the first electrodes 2 as stripe patterns on the first electrodes 2, a plurality of second electrodes 5 formed having similar patterns as the organic EL layers 4 on the organic EL layers 4, and a plurality of insulating film stripes 3b formed on the sidewalls of the organic EL layers 4 and on the first electrodes 2 between the adjacent organic EL layers 4. The plurality of insulating film stripes 3b are made of insulating materials having a lower optical damage threshold than the optical damage threshold of the substrate 1 or first electrodes 2.

Here, the laser beams can be selected from pulse type lasers having a wavelength in the range from 0.1 to 2 μm. For example, from a typical Q-switched Nd-YAG laser, fundamental beams having a wavelength of 1.06 μm with a pulse width of few ns, second harmonic beams having a wavelength of 0.531 μm, or third harmonic beams having a wavelength of 0.35 μm, can be selected and used as the irradiating laser beams. The wavelength of the laser beams is determined in consideration of the optical damage threshold of the insulating film stripes 3. Power of the laser beams is controlled over a few mJ, and an irradiation repeated ratio of the laser beam is controlled between 10 and 100 Hz to satisfy following conditions (1):

Conditions (1): optical damage threshold of the insulating films<laser power per unit area<optical damage threshold of the substrate

Here, when the commercial Q-switched Nd-YAG laser is used, laser power of 10⁵ J/s per pulse is obtained under the operation conditions of 10 ns (pulse width), 10 Hz and 1 mJ. When the laser beams are focused and irradiated to an area of 10 μm×100 μm, laser power of 10 GW/cm² is easily obtained per unit area. It is thus possible to induce the optical damage to the selected insulating film stripes by controlling the laser power without damaging the substrate. In addition, the laser beams may be focused through an optical system with lenses to have a beam width over 5 μm and then irradiated onto the insulating film stripes 3. Especially, the width of the focused laser beams is preferably controlled below the width of the insulating film stripes. When the width of the focused laser beams is smaller than that of the insulating film stripes, as shown in FIGS. 1d and 1e, the insulating film stripes 3a and 3b remain on the sidewalls of the organic EL layers 4 or on the sidewalls of the organic EL layers 4 and on the first electrodes 1 between the sidewalls of the adjacent organic EL layers 4 even after irradiation of the laser beams. As a result, even if a size of the OELD or organic semiconductor device is reduced and thus the pixel separation parts of the OELD or separation parts of the organic semiconductor device decrease, the pixels or devices are not electrically shorted but excellently separated.

In order to efficiently prevent the pixels from being contaminated by residual products of the insulating film stripes 3, the organic EL layers 4 and the second electrodes 5 after the laser beam irradiation, the laser beams are preferably irradiated under the degree of vacuum below 10⁻¹ Torr or non-moisture and non-oxygen insert gas flows such as Ar or He.

If the organic or inorganic insulating film stripes 3 are composed of materials having a high optical damage threshold, even though the organic EL layers 4 and the second electrodes 5 are removed by the laser beam irradiation, the insulating film stripes 3 can not be removed. In this case, fragments of the organic EL layers 4 and metal of the second electrodes 5 which are attached on the insulating film stripes 3 may optically react with the insulating film stripes 3 due to the irradiated laser beams, to generate unnecessary compounds on the insulating film stripes 3. In addition, if the attachment of fragments of the organic EL layers 4 and metal of the second electrodes 5 is strong, the organic EL layer 4 and the second electrode 5 are not completely removed from the surface of the insulating film. That is, the pixels are incompletely separated. However, in this embodiment of the present invention, the insulating film stripes 3 are composed of materials having high insulation and low optical damage threshold, and thus easily removed by the irradiated laser beams. And also, since the organic EL layers 4 and metal of second electrodes 5 are removed with the insulating film stripes 3, the pixels are completely separated.

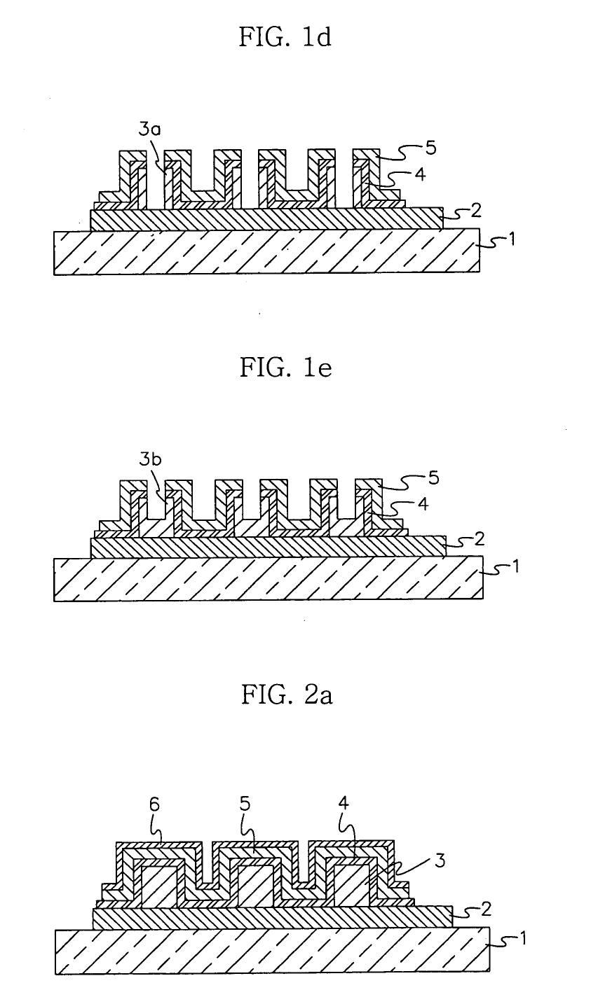

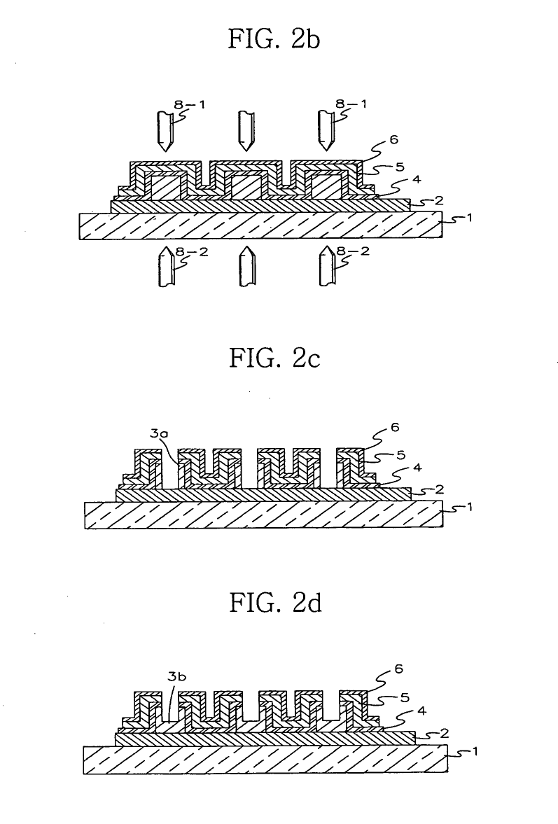

FIGS. 2a through 2d are cross-sectional diagrams illustrating the method for forming the pixels of the OELD in accordance with another embodiment of the present invention. Referring to FIG. 2a, first electrodes 2, insulating film stripes 3, organic EL layers 4 and second electrodes 5 are formed on a substrate 1 like FIGS. 1a and 1b, and laser beam absorption layers 6 are further formed on the second electrodes 5. The laser beam absorption layers 6 may be composed of a dye material such as an IR absorption dye, a metal or metal oxide such as black aluminum comprising aluminum oxide, or carbon black. For example, tetrakis amminium of the IR dyes, amminium dyes, dithiolene, nickel dyes, platinum and palladium dyes, phthalocyanine dyes, and antraquinones which are organic salt dyes produced by Epolon, Inc. can be used for the laser beam absorption layers 6.

Referring to FIG. 2b, focused laser beams 8-1 are irradiated from the upper side of the laser beam absorption layers 6 onto the insulating film stripes 3, or focused laser beams 8-2 are irradiated from the lower side of the substrate 1 onto the insulating film stripes 3. Accordingly, by the laser beam irradiation, the second electrodes 5 and the organic layers 4 are formed perpendicularly to the first electrodes 2 as stripes, thereby a plurality of separated pixels are formed.

During the pixel separation, the insulating film stripes 3 (in FIG. 1b), the organic EL layer 4, the second electrodes 5 and the laser beam absorption layers 6 which are sequentially formed, are removed to expose the first electrodes 2, as depicted in FIG. 2c, or are partially removed not to expose the first electrodes 2 but to expose the part 3b of insulating film stripes, as shown in FIG. 2d. Exposure of the first electrodes 2 can be determined in consideration of an irradiation time and strength of the laser beams and composition materials of the insulating film stripes 3. On the other hand, the laser beam absorption layers 6 are preferably formed outside the device, namely on the second electrodes or the device. The laser beam absorption layers 6 absorb and transform the laser beams into thermal energy, which results in rapid heating and bulk expansion. In the case that the laser beam absorption layers 6 are formed within the device or below the second electrodes, the inside of the device may be contaminated or damaged due to out-gassing of absorbed materials by the rapid heating.

The two aforementioned embodiments of the invention can be applied to a process for the pixel separation of an active matrix type OELD as well as a passive matrix type OELD. In addition to the pixel separation, the above-mentioned two embodiments can be used to cut or form complicated-shape of organic layers or electrode layers in the organic semiconductor devices formed on the substrate. That is, the insulating films having a low optical damage threshold are formed in a predetermined pattern shape on a substrate where a plurality of separated organic semiconductor devices will be formed, especially presumed separation parts, and then the organic semi-conducting layers are formed on the substrate. Laser beams are irradiated onto the upper side of the insulating films to form various shapes of organic layers or electrode layers. Here, at least one insulating film pattern can be used, and a shape of the insulating patterns can have curved shapes.

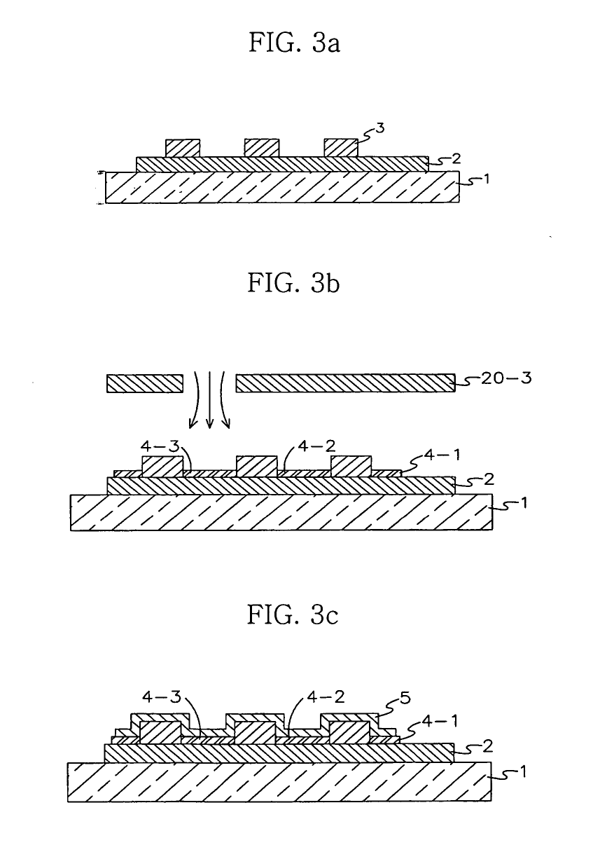

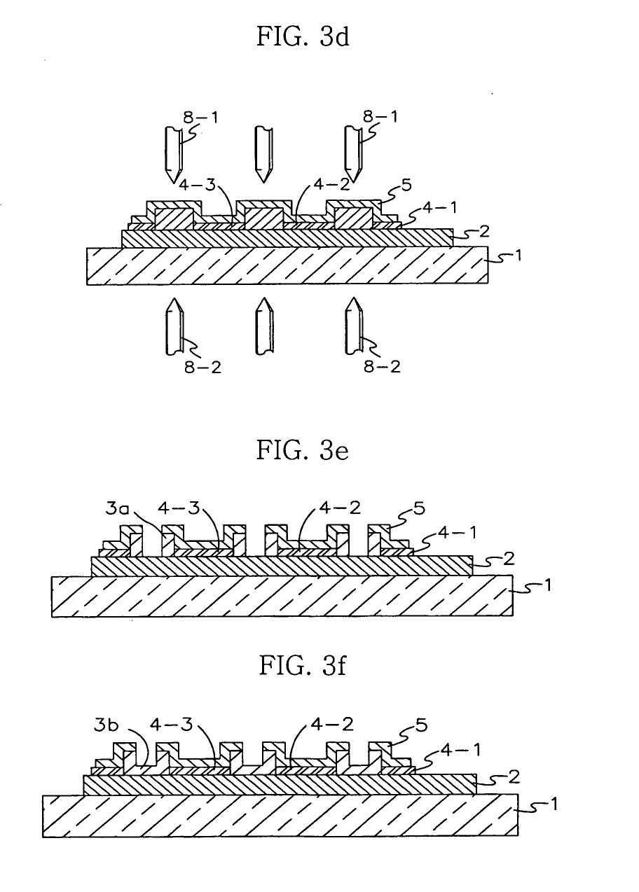

FIGS. 3a through 3f are cross-sectional diagrams illustrating a method for forming the pixels of the OELD in accordance with still another embodiment of the present invention, especially the method for sequentially forming R, G and B color organic EL layer by using a shadow mask, and separating color pixels by using a laser beam separation process. Referring to FIG. 3a, first electrodes 2 which are composed of material having a high work function such as ITO, are formed on a substrate 1 in a stripe shape, and organic or inorganic insulating film stripes 3 are formed perpendicularly to the stripes of the first electrodes 2 on the first electrodes 2 and the substrate.

Referring to FIG. 3b, a shadow mask 20-3 having a window is aligned on the first electrode 2 between the insulating film stripes 3, and organic EL layers 4-1, 4-2 and 4-3 which emit R, G and B light are sequentially formed between the insulating film stripes 3. Referring to FIG. 3c, second electrodes 5 having a low work function such as Al, Mg or Ca are formed on the whole surfaces of the insulating film stripes 3 and the organic EL layers 4-1, 4-2 and 4-3. Referring to FIG. 3d, focused laser beams 8-1 are irradiated from the upper side of the second electrodes 5 onto the insulating film stripes 3, or focused laser beams 8-2 are irradiated from the lower side of the substrate 1 onto the insulating film stripes 3, thereby simultaneously removing the insulating film stripes 3 and the second electrodes 5 formed on the insulating film stripes 3. Wherein the insulating film stripes 3 are entirely removed as shown in FIG. 3e or partially removed as shown in FIG. 3f in view of thickness. As a result, the second electrodes 5 are formed in a stripe patterns with separated pixels, thereby generating a plurality of color pixels. Here, an irradiation angle of the laser beams can be selectively determined.

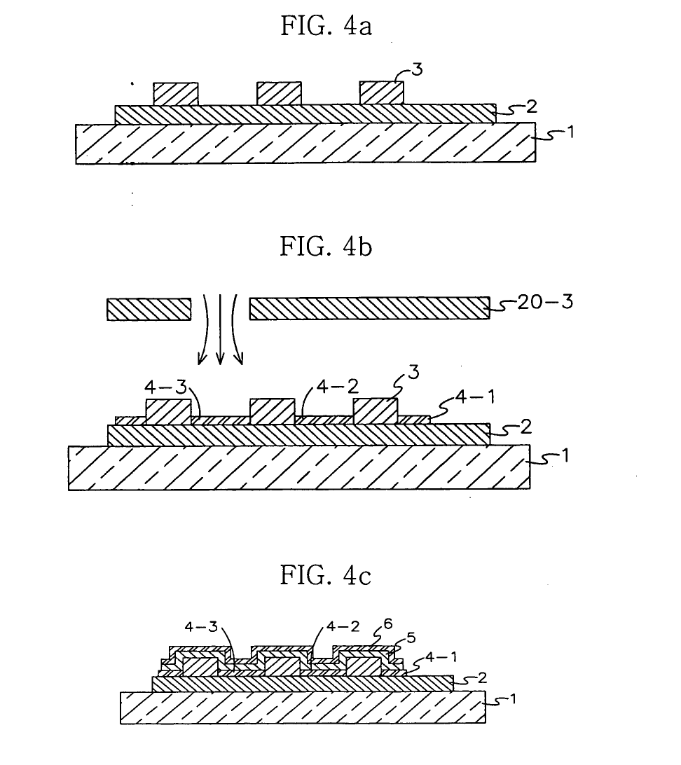

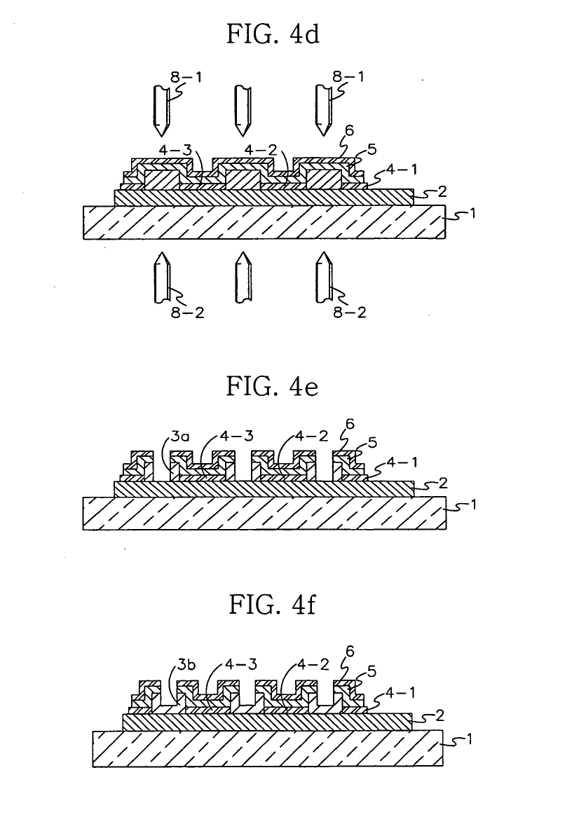

FIGS. 4a through 4f are cross-sectional diagrams illustrating a method for forming the pixels of the OELD in accordance with yet still another embodiment of the present invention. The insulating film stripes 3, organic EL layers 4, and the second electrode 5 are formed on first electrodes 2 and laser beam absorption layers 6 are further formed on second electrodes 5. Then laser beams 8-1 and 8-2 are irradiated to separate the second electrodes 5, thereby forming a plurality of color pixels.

The two aforementioned embodiments of the invention can be applied to the pixel separation of an active matrix type OELD as well as a passive matrix type OELD. In addition to the pixel separation, the two embodiments can be used to cut or separate organic layers or electrode layers having complicated shape in the organic semiconductor devices as in FIGS. 1a through 1e and FIGS. 2a through 2d.

### EXAMPLE

The process of manufacturing the OELD comprising a plurality of separated pixels will be explained. First electrodes composed of ITO are formed in stripe patterns on a glass substrate having a thickness of 1 mm. Insulating film stripes are formed perpendicularly to the stripes of the first electrodes on the glass substrate where the first electrodes are formed, by using a negative photo resist (DTFR-N250, Dongjin Semichem Co. LTD) having a low optical damage threshold. A width of the insulating film stripes is 30 μm and a thickness thereof is 5 μm. Organic compound layers including CuPc of 100 nm as a hole injecting layer, α-NPD of 400 nm as a hole transporting layer and Alq3 of 500 nm as a light-emitting layer are formed on the substrate where the insulating film stripes are formed. Second electrodes made of Al:Li of 2000 Å are formed on the organic compound layers. Q-switched Nd-YAG laser beams having a wavelength of 1.061 μm with pulse width of 10 ns, energy per pulse of 10 mJ and repeated irradiation ratio of 10 Hz are focused through a lens system, thereby producing focused beams having a beam diameter of 10 μm. The focused beams are irradiated from the upper side of the second electrodes onto the insulating film stripes. That is, the focused beams are irradiated and scanned on the insulating film stripes, and thus the insulating film stripes are removed to expose the first electrodes. In addition, only the organic layers and second electrodes positioned on the insulating film stripes are removed at the same time, and thus the second electrodes in the form of stripe patterns are formed to produce a plurality of pixels. Complete separation of the pixels from the second electrodes is confirmed by measuring infinite resistances between the second electrodes separated by optical damage. In addition, CuPc layer of 200 nm is further formed on the second electrodes as a laser beam absorption layer. The laser beams are irradiated in the same manner to remove the second electrodes. Thus, the second electrodes are formed in stripe patterns to produce a plurality of pixels separated. Complete separation of the second electrodes is also confirmed by measuring infinite resistances between the second electrodes.

It should be recognized that though the present invention is described with reference to the only OELD of the organic semiconductor devices, it is not limited thereby. In the case of a pentacene organic TFT where inorganic layers are formed on a substrate and organic layers are formed after formation of electrodes, a structure of a substrate-electrode-organic layer is formed. Therefore, insulating films having a low optical damage threshold are formed on the substrate where the electrodes have been formed, and the organic layers are formed thereon; or the insulating films having a low optical damage threshold are formed on the substrate, and then the electrodes and organic layers are formed thereon. And then laser beams are irradiated and scanned from the upper side of the insulating films, to form a plurality of organic TFTs.

In the case that the method for manufacturing the OELD is applied to the method for manufacturing organic semiconductor devices such as organic light emitting diodes, organic FET, organic TFT and organic SIT, element separation in high integration device can be easily obtained by applying the present invention. Especially, since the insulating film stripes are composed of materials with high insulation and a lower optical damage threshold, they are easily removed by the laser beam irradiation. Further, the organic layers and electrode metals formed on the insulating films are removed at the same time, thereby manufacturing the completely shaped devices, and improving operation reliability and yield thereof. As discussed earlier, complicated shapes such as through-holes are easily cut and formed in the organic semiconductor devices by using the insulators having a lower optical damage threshold and optical damage phenomenon.

While the invention has been shown and described with reference to certain preferred embodiments thereof, it will be understood by those skilled in the art that various changes in form and details may be made therein without departing from the spirit and scope of the invention as defined by the appended claims.

1. A method for manufacturing a plurality of organic semiconductor devices, comprising the steps of:
preparing a substrate on which a plurality of organic semiconductor devices will be formed;
forming insulating film patterns in regions of separation parts among the organic semiconductor devices, said insulating films composed of insulating materials having a lower optical damage threshold than the optical damage threshold of the substrate;
forming organic layers on the substrate where said insulating film patterns are formed; and
irradiating focused laser beams onto said insulating film patterns so as to entirely remove only said organic layers positioned on said insulating film patterns and then partially or entirely remove said insulating film patterns in view of thickness, thereby manufacturing said plurality of separated organic semiconductor devices.

2. The method of claim 1, further comprising a step for forming electrodes on said organic layers after the step for forming said organic layers and before the step for irradiating the laser beams, wherein in the step for irradiating the laser beams, only said organic layers and said electrodes which are positioned on the insulating film patterns are entirely removed, and said insulating film patterns are partially or entirely removed in view of thickness.

3. The method of claim 1, further comprising a step for forming first electrodes having at least one shape of patterns on the substrate after the step for preparing said substrate and before the step for forming said insulating film patterns, wherein in the step for irradiating the laser beams, only said organic layers positioned on the insulating film patterns are entirely removed, and the insulating films are removed partially or entirely in view of thickness.

4. The method of claim 1, further comprising a step for forming first electrodes whose pattern is more than one shape on the substrate after the step for preparing the substrate and before the step for forming the organic layers, and a step for forming second electrodes on the organic layers after the step for forming the organic layers and before the step for irradiating the laser beams, wherein in the step for irradiating the laser beams, only said organic layers and said second electrodes positioned on said insulating film patterns are entirely removed, and the insulating films are removed partially or entirely in view of thickness.

5. The method of claim 1, wherein said insulating film patterns are composed of photo resists, dry resists, organic insulators, or combinations thereof.

6. The method of claim 1, wherein said laser beams are pulse type of laser beams having a wavelength in the region from 0.1 to 2 μm.

7. The method of claim 1, wherein the laser beams are irradiated under the vacuum or non-moisture and non-oxygen inert gas flows.

8. The method of claim 1, wherein a width of the laser beams is less than that of the insulating film patterns.

9. The method of claim 1, further comprising a step for forming laser beam absorption layers on said organic layers or said electrodes before the step for irradiating the laser beams so that laser beam absorption is improved during the laser beam irradiation.

10. The method of claim 4, further comprising a step for forming laser beam absorption layers on the second electrodes, after the step for forming said second electrodes and before the step for irradiating the laser beams, so that laser beam absorption is improved during the laser beam irradiation.

11. An organic semiconductor device, comprising:
a substrate;
organic layers which are separately formed on the substrate using an optical damage by laser beams, pattern of said organic layers being more than one shape; and
insulating film patterns formed on the sidewalls of said organic layers, and composed of insulating materials having a lower optical damage threshold than the optical damage threshold of said substrate.

12. The device of claim 11, wherein said insulating film patterns are formed between the adjacent organic layers as well as the sidewalls of said organic layers.

13. The device of claim 11, wherein the insulating film patterns are composed of photo resists, dry resists, organic insulators, or combinations thereof.

14. The device of claim 11, further comprising electrodes formed between the substrate and the organic layers or on the organic layers.

15. The device of claim 14, further comprising laser beam absorption layers formed on the organic layers under which the electrodes are formed, or on the electrodes positioned on the organic layers, for improving laser beam absorption during the laser beam irradiation.

16. The device of claim 11, further comprising first electrodes formed between the substrate and the organic layers, and second electrodes formed on the organic layers.

17. The device of claim 16, further comprising laser beam absorption layers formed on the second electrodes, for improving laser beam absorption during the laser beam irradiation.
